(19) United States
(12) Patent Application Publication
(10) Pub. No.: US 2025/0191929 A1
(43) Pub. Date: Jun. 12, 2025

(54) LAYER BY LAYER ETCH PROCESS

(71) Applicant: Tokyo Electron Limited, Tokyo (JP)

(72) Inventors: Alec Dorfner, Albany, NY (US); Minjoon Park, Albany, NY (US)

(21) Appl. No.: 18/531,276

(22) Filed: Dec. 6, 2023

(51) Int. Cl. H01L 21/311; H01L 21/02; H01L 29/66; H10B 41/27; H10B 43/27

(52) U.S. Cl. CPC H01L 21/31144; H01L 21/0228; H10D 30/025; H10B 41/27; H10B 43/27

(57) ABSTRACT

A method of forming a device, the method includes loading a substrate into an etch chamber, the substrate including an underlayer and a pair of a first layer and a second layer, the pair being stacked to form a layer stack. The method further includes forming a patterned hard mask layer over the layer stack, the patterned hard mask layer including a pattern for forming a first set of features and a second set of features. And the method further includes performing a cyclic etching process to etch through the layer stack, each cycle of the cyclic etching process including a first etch step to selectively etch the first layer and a second etch step to selectively etch the second layer, and where the cyclic etching process forms the first and second set of features, the first having a different etch rate than the second set of features.

### TECHNICAL FIELD

The present invention relates to the field of semiconductor manufacturing and, more specifically, to a layer by layer etch process.

### BACKGROUND

Conventional NAND flash memory devices have historically been fabricated using planar (2D) structures. These planar NAND devices are limited in their ability to scale down in size, leading to difficulties in increasing memory densities while maintaining acceptable performance and reliability. The limitations of 2D NAND flash memory are primarily attributed to issues such as cell-to-cell interference, data retention, and programming/erasing endurance.

To overcome these limitations, the semiconductor industry has transitioned to 3D NAND technology, which offers a fundamentally different architecture. In 3D NAND devices, memory cells (transistors) are stacked vertically in multiple layers, allowing for a significant increase in storage capacity without the need for aggressive scaling of planar structures. Vertical stacking of memory cells enables each layer to be accessed independently, reducing cell-to-cell interference and improving overall memory device performance.

While various techniques have been developed for 3D NAND fabrication, there remains room for innovation and improvement in the field. Current fabrication methods incorporate non-selective etch processes that incorporate multiple discrete etch steps to etch the various features (such as contacts and slits) of different critical dimensions (CDs) and different shapes of the 3D NAND devices. Conventional 3D NAND fabrication methods etch layer stacks comprising alternating silicon oxide and silicon nitride layers (ON).

### SUMMARY

In accordance with an embodiment of the present invention, a method of forming a device, the method includes loading a substrate into an etch chamber, the substrate including an underlayer and a pair of a first layer and a second layer, the pair being stacked to form a layer stack. The method further includes forming a patterned hard mask layer over the layer stack, the patterned hard mask layer including a pattern for forming a first set of features and a pattern for forming a second set of features. And the method further includes using the patterned hard mask layer as an etch mask, performing a cyclic etching process to etch through the layer stack and expose the underlayer, each cycle of the cyclic etching process including a first etch step to selectively etch the first layer and a second etch step to selectively etch the second layer, the cyclic etching process being performed for a total number of cycles correlated to a total number of pairs in the layer stack, and where the cyclic etching process forms the first set of features and the second set of features, the first set of features having a different etch rate than the second set of features.

A method of forming a device, the method includes loading a substrate into an etch chamber, the substrate including an underlayer. The method further includes performing a first cyclic process to deposit a layer stack including alternating oxide and nitride layers, the first cyclic process including 2ⁿ cycles to form 2ⁿ alternating oxide and nitride layers, where n is an integer greater than 5. The method further includes forming a patterned hard mask layer over the layer stack, where the patterned hard mask layer includes a pattern for forming a first set of high aspect ratio features and a pattern for forming a second set of high aspect ratio features. And the method further includes using the patterned hard mask layer as an etch mask, performing a second cyclic process to etch through the 2ⁿ alternating oxide and nitride layers of the layer stack and expose the underlayer, each cycle of the second cyclic process including a first etch step to selectively etch the oxide layer and a second etch step to selectively etch the nitride layer, a total number of cycles in the second cyclic process being n, and where the second cyclic process forms the first set of high aspect ratio features and the second set of high aspect ratio features, the first set of high aspect ratio features having a different etch rate than the second set of high aspect ratio features.

And a method of forming a 3D NAND device, the method includes having a substrate including an underlayer and a layer pair of a silicon oxide layer and a silicon nitride layer, the pair being stacked to form a layer stack. The method further includes determining a total number of layer pairs in the layer stack, where the total number of layer pairs is greater than 2ⁿ, where n is an integer greater than 5. The method further includes determining a number of etch cycles for a cyclic etching process based on the total number of layer pairs. The method further includes etching a plurality of gate patterns and channel holes through the layer stack using the cyclic etching process, the cyclic etching process being repeated for the number of etch cycles, each cycle including a first etching process to selectively etch the oxide layer and a second etching process to selectively etch the nitride layer. And the method further includes filling the plurality of gate patterns with a gate stack material and the channel holes with a channel material.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A is an example of a semiconductor device that may be fabricated using the cyclic etching process of this disclosure;

FIG. 1B is an illustration in a cross-sectional view of a device during fabrication, in accordance with an embodiment of this disclosure, illustrating a layer stack substrate with a patterned photo resist layer and may be etched using an embodiment cyclic etching process;

FIG. 1C is an illustration in a cross-sectional view of a device during fabrication, in accordance with an embodiment of this disclosure, illustrating a layer stack substrate with a patterned hard mask layer that may be etched using an embodiment cyclic etching process;

FIG. 1D is an illustration in a cross-sectional view of a device during fabrication, in accordance with an embodiment of this disclosure, illustrating a layer stack substrate with etched features of various high-aspect-ratios and critical dimensions fabricated using an embodiment cyclic etching process;

FIG. 1E is an illustration in a cross-sectional view of a device during fabrication, in accordance with an embodiment of this disclosure, illustrating a layer stack substrate with etched features of various high-aspect-ratios and critical dimensions that was etched using an embodiment cyclic etching process and was filled with an appropriate conductive material for gate formation;

FIG. 1F is a flowchart of the cyclic etching process in accordance with an embodiment of this disclosure;

FIG. 2A-2E illustrate cross-sectional views of layer stack substrates that have been etched using the same selective etch process with varying timeframes, and the illustrations may be used to describe the method of determining the timeframe of an etch cycle in various embodiment of this disclosure;

FIG. 3A-3B are schematic plots of the intensity of an etching tool over a timeframe and corresponding layer stack substrates that have different amounts of etched layers corresponding to the different points of the etching process illustrated in the plots; and

FIG. 4 is a system diagram of a plasma etching tool implementing the etching process of this disclosure, in accordance with an embodiment.

### DETAILED DESCRIPTION OF ILLUSTRATIVE EMBODIMENTS

As semiconductor device size decreases to the sub-nanoscale and the device integration changes from two dimensional to three dimensional structures, continued device scaling demands high precision selective etch technology. The wide variety of features used in a single semiconductor device have led to highly complex and time-consuming semiconductor device fabrication processes. Traditionally, the wide variety of features in a single semiconductor device are fabricated through a wide range of different etching steps. Modern semiconductor devices incorporate features of high-aspect-ratios (HARs) and various critical dimensions (CDs) to achieve their intended functionality. Current etching processes are unable to etch features of different HARs and CDs simultaneously, because significant over etch (OE) occurs on features that have different etch rates (ERs). This may be the result of current etching processes implementing non-selective methods and is referred to as either CD loading or pattern loading (depending on the features being etched). Current non-selective etching processes etch through a top layer and land on an underlayer with a small bottom critical dimension (BCD), which increases as over etch time extends.

The etch depth of current non-selective etching processes depends on the etch time, meaning that high-aspect-ratio (HAR) features take a long time to etch. However, each die generally includes features of different CD and aspect ratio features that have to be etched. For example, channel holes for forming the channel stack may have a very high aspect ratio (larger than 1:90, for example) while a slit/trench for forming the gates may have a lower aspect ratio (less than 1:100). While a slit/trench feature may have a similar 2D cross section and aspect ratio to that of a channel hole, the 3D shapes of the features are drastically different. For example, the fluxes into a 100:1 slit/trench are different from fluxes into a 100:1 circular channel hole. Because of various loading effects, e.g., due to pattern density and aspect ratio variation, conventional processes (if the features are etched simultaneously) end up over etching the lower aspect ratio features when the etch time is designed to etch the high aspect ratio features. On the other hand, when the etch time is designed to etch the lower aspect ratio features without damaging underlying layers, the higher aspect ratio features are not fully opened. In other words, current semiconductor device fabrication processes use non-selective etching processes to etch features of various CDs and HARs in separate discrete steps. The non-selective etching processes are not able to etch various features of different CDs and HARs simultaneously, and can result in poor product yield. Of course, different features could be etched at different times (which is what current non-selective etching processes do) but that would require a complex masking strategy increasing manufacturing costs.

Embodiments discussed in this disclosure describe a 2-step cyclic selective etching process that can simultaneously etch features of varying CDs and HARs without over etching underlayers, and that can reduce the total etch time.

This disclosure describes a cyclic etching process that, by selectively etching layers of a layer stack substrate, may be used to etch high-aspect-ratio contacts (HARC) and features of varying CDs, simultaneously (as opposed to separate steps). The cyclic etching process comprises performing multiple etch cycles, where each etch cycle comprises switching between a first etch step and a second etch step. The first etch step selectively etches a first layer and the second etch step selectively etches a second layer. The cyclic etching process maintains a wide etch front, which may achieve large bottom CDs without a long over etch time. In an embodiment, the size of the etch front can be controlled throughout the cyclic etching process.

A benefit of the cyclic etching process of this disclosure may be that the etch depth depends on the number of etch cycles, not process time. Each etch step's etch time (etch time being the amount of time the etching tool etches using that selective etch step) may be determined based on the feature with the slowest etch rate (e.g., a pillar), which could be the feature, e.g., with the highest pattern density and aspect ratio. Due to the etch steps being selective, such a slower etch rate feature may be etched for the longer amount of time needed to finish etching this feature without over etching features that etch faster. Uniform etch depth may be achieved across a wide range of features with different CDs and patterns (e.g., line and space versus a hole). As a result, the cyclic etching process can simultaneously etch various different high-aspect-ratio features without causing over etching. And by merging HAR etch steps together, the cyclic etching process reduces the raw process time (RPT) and increases throughput. This is accomplished by reducing the number of overall etch steps used in the semiconductor fabrication process, which enables manufacturers to overcome CD and pattern loading in merge schemes for layer stack etching.

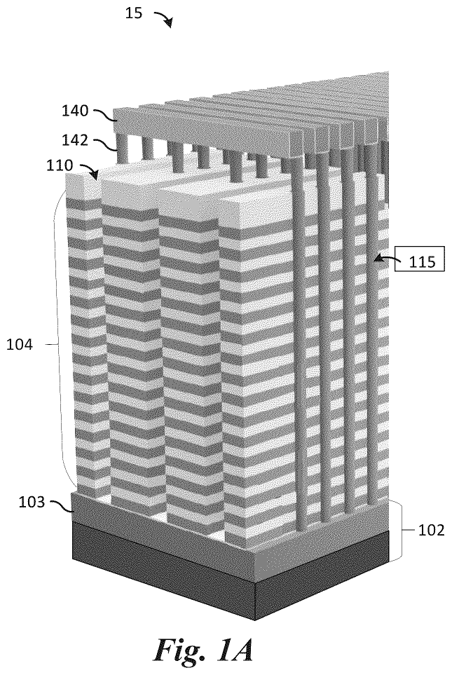

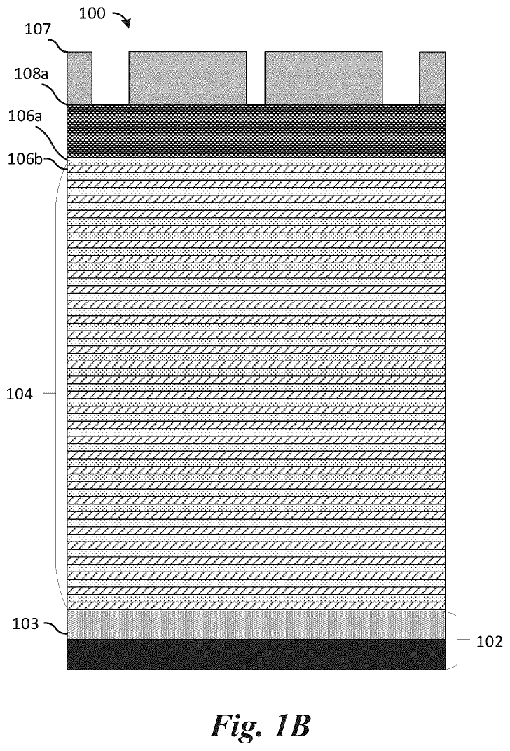

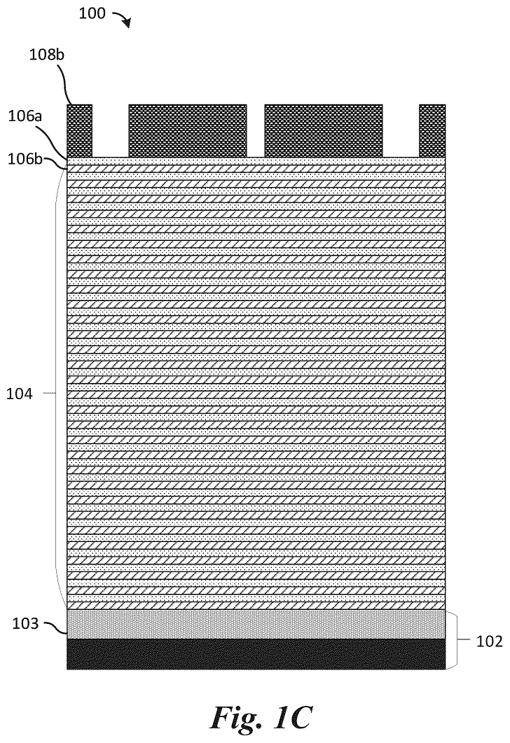

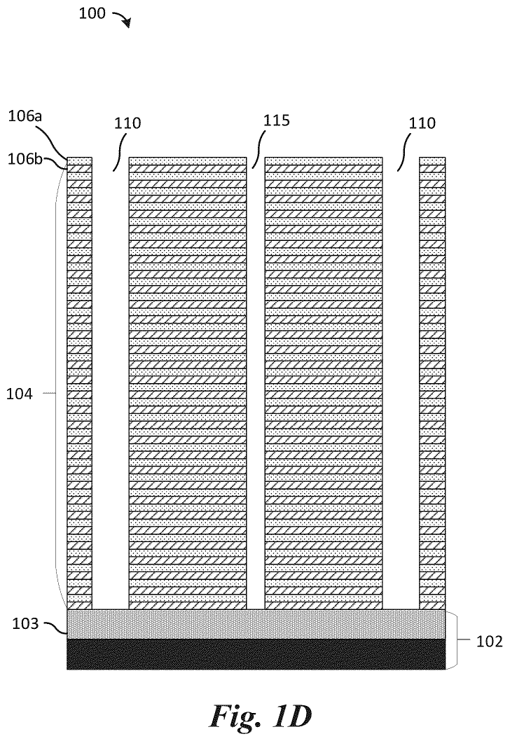

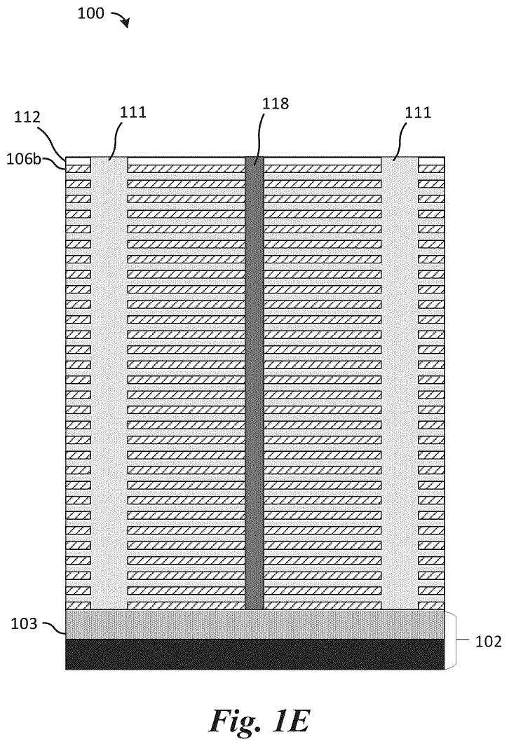

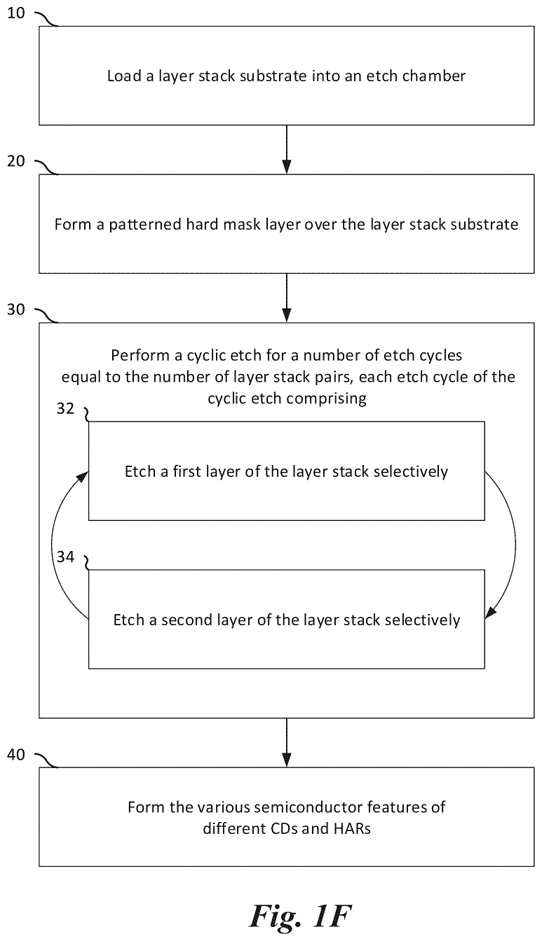

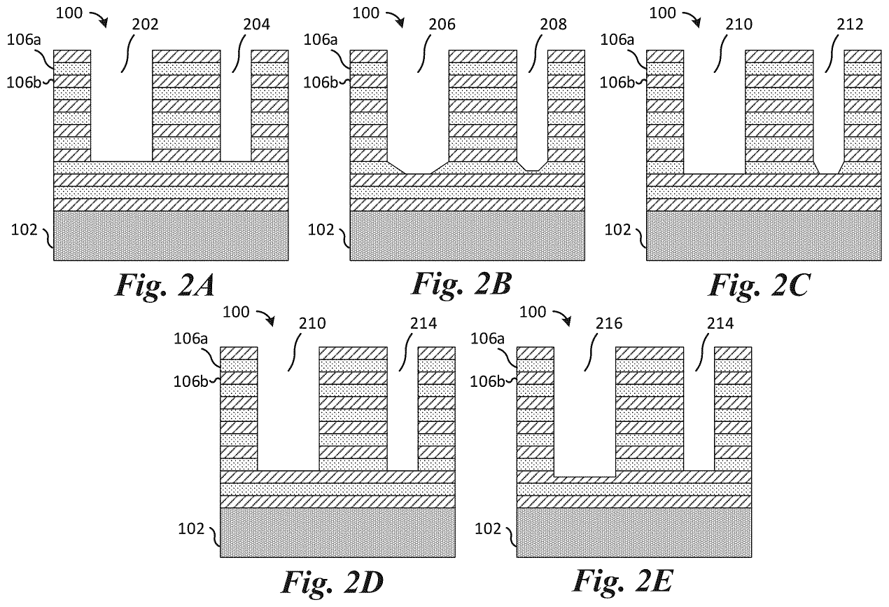

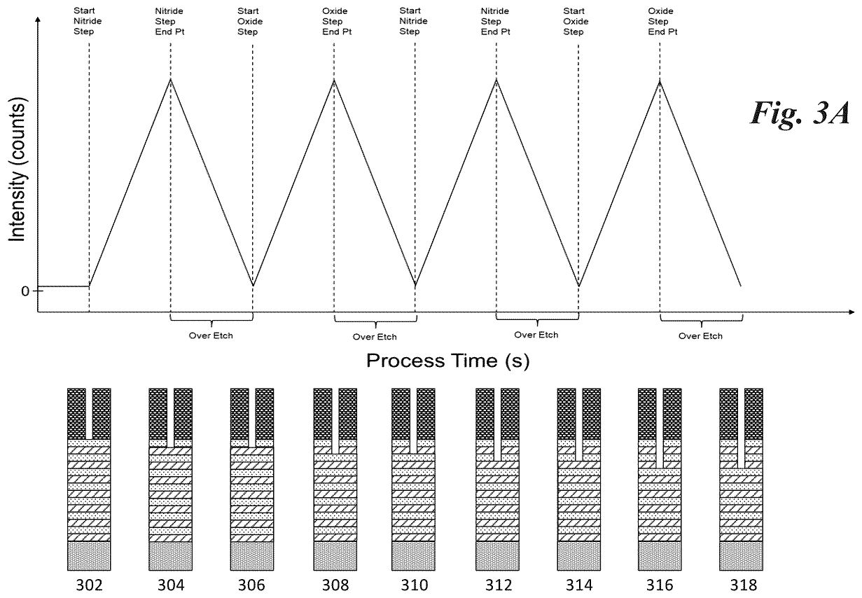

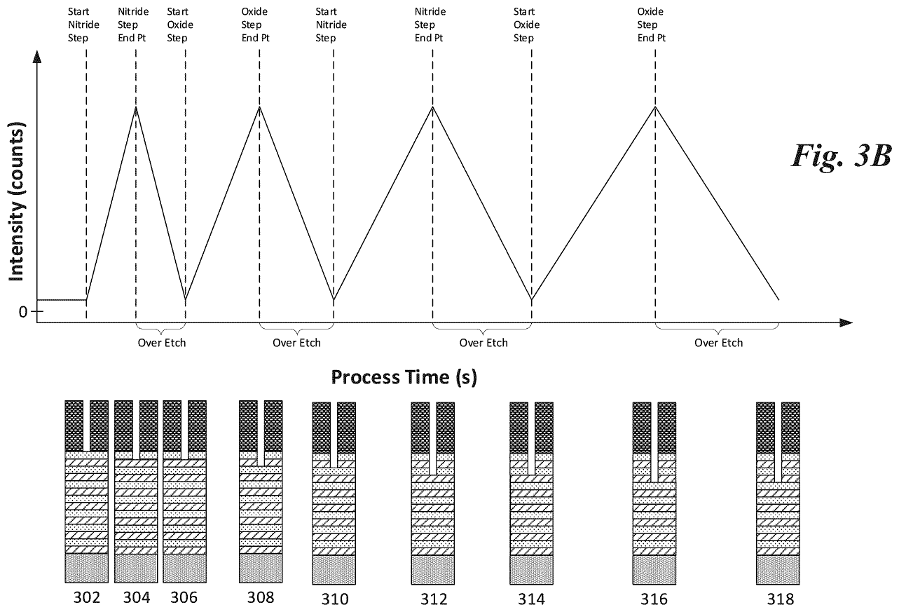

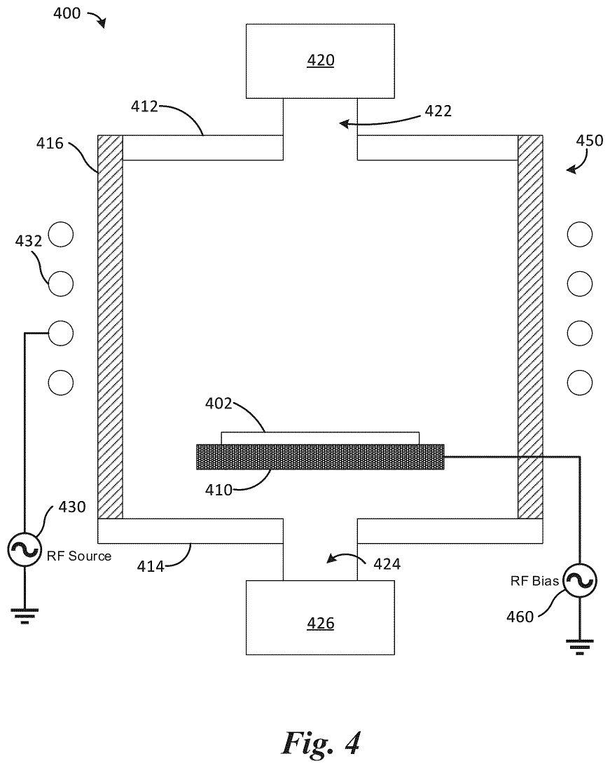

In order to best describe the cyclic etching process, this disclosure begins with a description of an example semiconductor device in FIG. 1A and a fabrication process using an embodiment cyclic etching processing FIGS. 1B-1E along with the flow chart of FIG. 1F. An embodiment method of determining the etch time of an etch cycle will be described using FIGS. 2A-2E. Examples of etch times will be illustrated and described using FIGS. 3A-3B and an example plasma system for implementing the embodiments described using FIG. 4.

FIGS. 1A-1E are illustrations of a semiconductor device fabricated using an embodiment of the cyclic etching process of this disclosure.

FIG. 1A illustrates a projection view of a semiconductor device with high aspect ratio contact (HARC) features that may be fabricated using an embodiment cyclic etching process of this disclosure. This figure could be a 3D NAND but in different embodiments other type of device structures with HARC features may be formed. FIG. 1A illustrates the structure after the cyclic etching process and also after some subsequent fill process for illustration.

The semiconductor structure 15 comprises a substrate 102, such as a semiconductor substrate and further comprises an underlayer 103. In various embodiments, the underlayer 103 may comprise a semiconducting material, a conducting material, or an etch stop layer. The semiconductor structure 15 comprises a layer stack 104 in which multiple layers of transistors are formed. The semiconductor structure 15 further comprises features of differing CDs having HARs, e.g., having aspect ratios greater than 1:10, e.g., 1:50. Examples include a trench or a split 110 filled with a gate material (illustrated as not being filled for clarity) and a channel hole 115 filled with a channel stack. The semiconductor structure 15, in an embodiment, may further comprise a metal filled bit line 140 coupled with a metal filled bit line contact (BLC) 142 coupled to the channel stack in the channel hole 115.

As a result of the various features of the example semiconductor structure 15 of FIG. 1A, the fabrication process for FIG. 1A may benefit from the cyclic etching process of this disclosure. Not only would the selectivity of the cyclic etching process reduce over etch of underlayers of the semiconductor structure 15, but the fabrication process is simpler and does not depend on overall etch time.

A detailed description of the cyclic etch process will be described using FIGS. 1B-1E and the flow chart of FIG. 1F.

FIG. 1B illustrates a cross-sectional view of a layer stack substrate 100 during a fabrication process using an embodiment cyclic etching process of this disclosure. The patterned photo resist layer 107 may comprise a features pattern to enable etching of the feature pattern into the unpatterned hard mask layer 108a. In an embodiment, only the exposed regions of the unpatterned hard mask layer 108a would be etched to form the feature pattern to prepare the layer stack 104 to have multiple features of differing high-aspect-ratios etched simultaneously.

In an embodiment, the layer stack substrate 100 comprises the substrate 102, the layer stack 104, an unpatterned hard mask 108a, and a patterned photo resist layer 107. As discussed earlier with FIG. 1A, the layer stack 104 comprises the plurality of alternating layers of the first layer 106a and the second layer 106b. In an embodiment, the patterned photo resist layer 107 may have been patterned using one or more lithography processes. As will be more clear further below, the patterned photo resist layer includes different types of high aspect ratio features such as channel holes and gate trenches that are generally formed in different steps.

In an embodiment, the substrate 102 may be a silicon substrate. In other embodiments, the substrate 102 may alternatively or additionally include other suitable semiconductor material, such as germanium, silicon germanium, silicon carbide, or gallium arsenide.

In various embodiments, the layer stack 104 comprises a plurality of layer pairs, e.g., a plurality of alternating semiconductor layers of the first layer 106a and the second layer 106b, in an embodiment. Each layer pair comprises a single first layer 106a and a single second layer 106b stacked on top of each other. A single layer could include multiple monolayers having similar composition in various embodiments. The layer stack 104 may then be described as comprising a plurality of alternating layer pairs. In an embodiment, the first layer 106a may vary in thickness between 1 nm to 10 nm, and the second layer 106b may vary in thickness between 1 nm to 10 nm. In an embodiment, the first layer 106a may be silicon nitride and the second layer 106b may be silicon oxide. In other embodiments, the first layer 106a may be silicon germanium and the second layer 106b may be silicon when used to build FinFETs or nanosheet transistors. In various other embodiments, the first layer 106a and the second layer 106b are comprised of suitable materials for the fabrication of a semiconductor device where the cyclic etching process of this disclosure may be used to etch the first layer 106a and the second layer 106b.

Although layer stack 104 is shown to include a particular number of layers, layer stack 104 may include any suitable number of layers, including in upwards of one-hundred layers, two-hundred layers, three-hundred layers, four-hundred layers, five-hundred layers, or more (potentially hundreds more).

In an embodiment, the hard mask layer 108a may be a metal hard mask suitable for etching features of high-aspect-ratio. In various embodiments, the hard mask layer 108a may include a layer made of a metal such as tungsten (W), titanium-tungsten (TiW), or titanium nitride (TiN), or any other metal that provides the required selectivity for high-aspect-ratio etching processes.

FIG. 1C illustrates a cross-sectional view of a layer stack substrate 100 after patterning the hard mask during a subsequent stage of fabrication. In one or more embodiments, the layer stack substrate 100 may be loaded into a etch chamber (box 10 of FIG. 1F) and the hard mask 108a is patterned to form a patterned hard mask layer 108b over the layer stack substrate (box 20 of FIG. 1F). The forming includes the patterning of the hard mask layer by etching the hard mask layer using the patterned photo resist layer as an etch mask.

In an embodiment, the etch chamber of the etching tool may be a plasma etch chamber of a plasma etching tool, such as the plasma etching tool illustrated, for example purposes, in FIG. 4. In an embodiment, the etching processes illustrated in FIGS. 1C and 1D may be performed in the same etch chamber.

In an embodiment, multiple features of differing high-aspect-ratios are included in the feature recipe patterned into the patterned hard mask layer 108b. An embodiment cyclic etching process of this disclosure may be used to simultaneously etch the various features of differing high-aspect-ratios in the patterned hard mask layer 108b.

FIG. 1D illustrates a cross-sectional view of a semiconductor structure during fabrication after etching through the layer stack in accordance with embodiment of this disclosure.

In various embodiments, a first openings 110, and a second opening 115 are formed through the layer stack substrate 100. In various embodiments, the first openings 110, the second opening 115 may be holes, trenches, vias, or any other suitable type(s) of openings.

In certain embodiments, the first openings 110 may be referred to as slits that ultimately will be used to deposit conductive material for one or more gates of a 3D semiconductor device. The first openings 110 may have any shape suitable for the opening specified in a feature recipe (such as both being slits) used to construct the semiconductor device.

In certain embodiments, the second opening 115 is a channel hole for forming channels of a 3D semiconductor device (e.g., of a 3D memory device, such as a 3D NAND device as shown in FIG. 1A). In certain embodiments, the second opening 115 can be used to form 3D memory cells, with channels for the 3D memory cells being formed in second opening 115. Further, single-level cell (SLC) memories, multi-level cell (MLC) memories such as triple-level cell (TLC) and quad-level cell (QTC) memories, and/or other memory or device structures can be formed using these techniques.

An embodiment cyclic etching process of this disclosure may be used to etch through the layer stack 104 to form the various openings of different CDs and HARs illustrated in FIG. 1D. In an embodiment where the first openings 110 are slits, and the second opening 115 is a channel hole, the cyclic etching process of this disclosure may be used to simultaneously etch the openings without damaging underlayers by over etching.

The recipe for the cyclic etching process may comprise a first etch time for a first layer selective etch step and a second etch time for a second layer selective etch step, as well as a number of etch cycles for the cyclic etching process.

The cyclic etching process performs a cyclic etch for a number of etch cycles equal to the number of layer stack pairs (box 30 of FIG. 1F). For example, if the number of layer stack pairs totals 64, the number of etch cycles would be 64, also.

The cyclic etch comprises performing the number of etch cycles according to a feature recipe, which may also be known from the deposition process of the layer stack. A single etch cycle comprises the etch step of box 32 and the etch step of box 34.

In box 32, a first selective etch step may be used to etch a first layer of the layer stack, selectively. In an embodiment, this may be done using a plasma etching process that selectively etches materials that the first layer may be comprised of by using a first specific gas chemistry. The first specific gas chemistry may target only the material of the first layer, and not be effective at etching the material of the second layer, i.e., selectively removes the first layer. For example, the etch rate of the first layer may be about 10% greater than the etch rate of the second layer using the first specific gas chemistry. In a further example, the etch rate of the first layer may be about 100% greater than the etch rate of the second layer using the first specific gas chemistry. The first selective etch step of box 32 further comprises etching for a first etch time. The first etch time may be a configurable amount of time predetermined in the feature recipe, which may have been determined using the etch time determining method illustrated in FIGS. 2A-2E. In other embodiments, the first etch time may be dynamic and vary depending on the total number of layers being etched (for example, etch times may be increased as etching progresses through the layer stack).

After the first selective etch step, the etch cycle proceeds with box 34. In box 34, a second selective etch step may be used to etch a second layer of the layer stack, selectively. In an embodiment, this may be done using a plasma etching tool that selectively etches materials that the second layer may be comprised of by using a second specific gas chemistry. The second specific gas chemistry may target only the material of the second layer, and not be effective at etching the material of the first layer. For example, the etch rate of the second layer may be about 10% greater than the etch rate of the first layer using the second specific gas chemistry. The second selective etch step of box 34 further comprises etching for a second etch time. The second etch time may be a configurable amount of time predetermined in the feature recipe, which may have been determined using the etch time determining method illustrated in FIGS. 2A-2E. In other embodiments, the second etch time may be dynamic and vary depending on how many layers may be etched through (for example, etch times may be increased as etching progresses through the layer stack due to the increase in aspect ratio as the etch progresses).

Each etch cycle etches a single layer stack pair. As a result, the etch depth of a feature correlates with the number of etch cycles performed (as opposed to the etch times of the separate selective etch steps). An advantage of using a selective etch step may be that over etch of underlying layers may be minimized due to the high selectivity of the etching. For example, the first selective etch step only targets materials of the first layer, which limits damage to the second layer once the first layer has been etched through.

The selectivity of the etch steps also have the advantage that features of differing etch rates, critical dimensions, or pattern density may be etched simultaneously due to the selective etch steps causing minimal over etch on the layer of the layer stack not selectively being etched. As a result, although large CDs features typically have a faster etch rate, the slower etch rate features may be etched fully without causing significant over etch of the large CD features, and thus the features may be etched simultaneously. For each layer, the etch time may be determined based on the smallest etch rate feature of the feature recipe without damaging the underlying layer due to over etching because of the selective nature of the etch step. In FIG. 1D, the cyclic etching process of box 30 in FIG. 1F may have been used to simultaneously etch the various features illustrated.

In various embodiments, the features may comprise HARCs. A significant advantage of the cyclic etching process of this disclosure may be the uniform etch depth that may be achieved across a wide range of features with different CDs and patterns.

Thus, an etch cycle of the cyclic process comprises selectively etching an uppermost layer using a selective etch step for a corresponding etch time (e.g., the first selective etch step etches for a first etch time). After the features have been etched through the uppermost layer using a selective etch step that corresponds to that uppermost layer, the etch cycle then switches to a new selective etch step that selectively etches the newly revealed uppermost layer for a new corresponding etch time. For example, in an embodiment, the first layer may be silicon oxide and the second layer may be silicon nitride. In that case, the first selective etch step selectively etches silicon oxide and the second selective etch step selectively etches silicon nitride. For example, the first selective etch step may include an etch gas for etching silicon nitride comprising fluorine gases such as CH₂F₂, CH₃F, CF₄, SF₆, and NF₃ that are mixed with O₂, N₂, H₂, or NO to ensure a high anisotropy and a high selectivity over silicon oxide and the second selective etch step may include an etch gas for etching silicon oxide comprising fluorine gases such as C₄F₆, C₄F₈, C₃F₈, CF₄, SF₆, and NF₃ that are mixed with O₂, or Ar to ensure a high anisotropy and a high selectivity over silicon nitride. A single etch cycle would etch through a single layer of silicon oxide and a single layer of silicon nitride. The cyclic etching process etches as many etch cycles as are specified in the feature recipe.

As another example, in an embodiment, the first layer may be Si and the second layer may be SiGe. In that case, the first selective etch step selectively etches Si and the second selective etch step selectively etches SiGe. For example, the selective etch steps may use fluorine gases mixed with O₂ to ensure a high anisotropy and a high selectivity. A selective etch step with lower fluorine gases and higher O₂ will etch Si faster than SiGe. A selective etch step with higher fluorine gases and lower O₂ will etch Si selectively. The first selective etch step and the second selective etch step may be tuned accordingly.

In various embodiments, the feature recipe also provides the first etch time and the second etch time. The etch time for a corresponding layer to be selectively etched may be a configurable number, in an embodiment.

FIG. 1E illustrates a cross-sectional view of the semiconductor structure during the fabrication of a semiconductor device after forming gate and channel in accordance with embodiment of this disclosure.

The various features are further processed to form the features of the feature recipe after the cyclic etch completes the corresponding number of etch cycles (box 40 of FIG. 1F). In an embodiment, this may comprise the various semiconductor features such as those illustrated in FIG. 1A. In other embodiments, the features of various CDs and HARs may comprise vias, and pillars that are etched simultaneously.

In an embodiment, the forming of features may comprise filling the etched openings of FIG. 1D with the appropriate conductive materials to form the features of the feature recipe for the semiconductor device.

After etching the layer stack substrate 100, a channel stack 118 comprising polysilicon may be formed within the channel hole. A gate material 111 may be used to fill the first openings 110. The gate material 111 may include a gate stack and may comprise a gate dielectric followed by a stack of conductive materials.

The layer stack substrate is illustrated to still include the first layer 106a in this embodiment, but in other embodiments, the first layer 106a material may be etched and filled with a new material for forming the semiconductor device, as well.

A mask layer 112 may be included, in certain embodiments, to enable filling of certain features and not others. For example, the mask layer 112 may have been used to cover the second opening 115 and to leave uncovered the first openings 110 for etching the second layer 106a and then subsequently filling with the gate material 111, which may be a different material than the conductive material to form the channel with channel material 118.

In the case of a 3D memory device, channel material 118 may include any material(s) suitable for use as a channel (or portion of a channel) of the 3D memory device. In certain embodiments, channel material 118 may include multiple material layers that include silicon, oxide, SiN, oxide, and silicon (e.g., SONOS structures). In certain embodiments, channel material 118 may include tungsten, alumina, nitride, oxide, and silicon (e.g., WANOS structures). In certain embodiments, channel material 118 may include an oxide-nitride-oxide (ONO) memory stack and polysilicon material to form the polysilicon channel. In certain embodiments, the second opening 115 of FIG. 1D may be filled with any of SiO₂, SiN, SiO₂ and polysilicon. For example, depositing channel material 118 may include depositing a layer of oxide (e.g., SiO₂), a layer of nitride (e.g., SiN), and another layer of oxide (e.g., SiO₂), with a remaining portion of the second opening 115 being filled with polysilicon. Channel material 118 may be deposited using any suitable type of deposition process or combination of deposition processes. For example, channel material 118 may be deposited using one or more of a CVD process (including, potentially, an ALD process), a PECVD process, a PVD process, a PEPVD process.

As illustrated in FIG. 1E, the first openings 110 of FIG. 1D may be filled with the gate material 111. The gate material 111 may be a metal-containing material appropriate for the corresponding fabrication process, such as for forming a 3D semiconductor structure (e.g., a 3D NAND device). In certain embodiments, the gate material 111 may be a metal-containing material suitable for use as a gate in the 3D semiconductor structure being formed. Although primarily described as a metal-containing material, the gate material 111 may be any suitable conductive material, such as any material that is suitable for acting as a gate in a transistor (e.g., a gate in a transistor of a 3D NAND memory device).

A method for determining the etch time for a specific feature recipe that includes multiple features of varying CDs and HARs will be discussed below.

A method for determining the etch time of the selective etch steps of the etch cycle may be illustrated in FIGS. 2A-2E, and discussed in the detailed description following.

FIGS. 2A-2E illustrate cross-sectional views of the layer stack substrate 100 undergoing a selective etch step of the cyclic etching process of this disclosure at different etch times. Though FIGS. 2A-2E illustrate the layer stack substrate 100 terminating at the edges, various embodiments are fabricated with the features repeating across the entire surface of a wafer being fabricated, which would appear as a grid of layer stack substrates 100 when viewed from above. FIGS. 2A-2E may be used as a method of determining the etch time of the selective etch step of the cyclic etching process, where each illustration corresponds to the layer stack substrate 100 having been etched for a different amount of time. All of the FIGS. 2A-2E illustrate the layer stack substrate 100, which comprise the semiconductor substrate 102, and a layer stack (comprised of the plurality of pair layers that each comprise the first layer 106b and the second layer 106a) on the semiconductor substrate 102. The layer stack substrate 100 further comprises two features (a higher etch rate feature and a lower etch rate feature) of different CDs being etched for different amounts of time.

FIG. 2A illustrates the layer stack substrate 100 at a first point in time that corresponds to the start of the second selective etch step of an etch cycle to selectively etch the second layer 106a, which may be the highest layer from the semiconductor substrate inside the features being etched. Illustrated in FIG. 2A are two features simultaneously being etched using the cyclic etching process of this disclosure at the start of the second selective etch step. The two features have different CDs and different ERs. There may be a large CD feature 202, and a small CD feature 204. Typically, large CD features have a higher etch rate and smaller CD features have a lower ER. In an embodiment, the large CD feature may be a slit and the small CD feature may be a channel hole. FIG. 2A may be used as the starting point in time to determine the etch time of the second selective etch step. The time illustrated in FIG. 2A may be called time t1.

FIG. 2B illustrates the same layer stack substrate 100 after the second selective etch step has etched to a time t2. After etching to the time t2, the large CD feature 202 has changed to a second time large CD feature 206, which has etched through the second layer, but has not been etched completely to form the feature. The small CD feature 204 has changed to a second time small CD feature 208, which has also not been etched completely through the second layer. As a result of both features not having completely etched their corresponding feature and that the second time small CD feature 208 has not etched through the second layer, the time t2 would be determined to not be enough time for the second etch time. Therefore, the second selective etch step will run for a longer etch time.

FIG. 2C illustrates the same layer stack substrate 100 after the second selective etch step has etched to a time t3. After etching to the time t3, the second time large CD feature 206 has etched the complete feature through the second layer to the first layer beneath and may be called a third time large CD feature 210. The second time small CD feature 208 has been etched further to a third time small CD feature 212. The third time small CD feature 212, though it has now etched through the second layer and exposed the first layer beneath, has not been fully etched. As a result of the third time small CD feature 212 not being completely etched, the time t3 would be determined to again not be enough time for the second etch time. Therefore, the second selective etch step will run for a longer etch time.

FIG. 2D illustrates the same layer stack substrate 100 after the second selective etch step has etched to a time t₄. After etching to the time t₄, the third time large CD feature 210 remains at the same etch depth and same feature shape. This may result because the second layer has been fully etched through to reveal the first layer beneath and the second selective etch step has minimal impact on the first layer. The third time small CD feature has now been completely etched through the second layer to reveal the first layer and the feature has been completed and may be called a fourth time small CD feature 214. After examining the etch features (the third time large CD feature 210 and the fourth time small CD feature 214), the time t₄ would be determined to be the correct second etch time for the second etch step. There was negligible over etch on the third time large CD feature and there was enough time for the fourth time small CD feature to complete the feature and etch through the second layer.

It should be noted that the etch time illustrated in FIG. 2D would be determined as the optimal second etch time for the second etch step. Though that may be the optimal etch time, there may be cases where the second etch step etches for too long. As a result, to completely describe how to determine a correct etch time for an etch step, FIG. 2E may be used to illustrate the case when the etch time was too long and caused over etch of the large CD feature (the higher etch rate feature).

FIG. 2E illustrates the same layer stack substrate 100 after the second selective etch step has etched to a time t₅. After etching to the time t₅, the third time large CD feature 210 has now been over etched through the first layer a non-negligible amount, and resulted in a fifth time large CD feature 216. On the other hand, the fourth time small CD feature 214 has experienced a negligible amount of over etch which has not changed the feature shape. As a result of over etching to the fifth time large CD feature 216, the time t₅ would be determined as too long for the second etch time of the second etch step.

The method for determining the second etch time illustrated in FIGS. 2A-2E may also be used to determine the first etch time of the first etch step, in an embodiment. Once the etch times for both the first etch step and the second etch step have been determined, they may be incorporated into a feature recipe to be used to etch a wafer lot. As illustrated in FIGS. 2A-2E, the etch time depends on the total amount of time for the small CD (or slowest ER) feature to be fully etched. Once enough time has passed that the small CD feature has been fully etched, the etch cycle will switch to the next etch step (or to starting a new etch cycle back at the first layer of a new layer pair). It should be noted that the method illustrated in FIGS. 2A-2E may be used to determine the etch time for an etch step of the etch cycle for cases where the etch time to finish a feature through a layer of the layer stack does not vary with time.

In another embodiment, the method of determining the etch time of a selective etch step discussed above may also be implemented by etching a set of wafers using the same patterned hard mask, but each wafer may be etched for a different amount of time. The wafers may then be examined to determine which wafer's features were etched to a point consistent with the illustrated layer stack substrate 100 of FIG. 2D (the layer stack substrate was etched for long enough to form the smallest etch rate feature fully without over etch of the layer underneath in the higher etch rate features). The etch time for the corresponding selective etch step of the etch cycle would be set to the amount of time that particular wafer was etched for. In the same embodiment, the same method may then be used to determine the etch time for the selective etch step of the second layer.

The illustrations of the etching intensity of an etching tool for a constant etch time and a dynamic etch time will be discussed in FIGS. 3A-3B.

FIGS. 3A-3B illustrate two different plots of the etching intensity over time for the cyclic etching process of this disclosure, and the corresponding etch results are illustrated below the plots. The etching intensity over time plot of FIG. 3A illustrates an embodiment where the cyclic etching process incorporates a constant timeframe for both selective etch steps. The etching intensity over time plot of FIG. 3B illustrates an embodiment where the cyclic etching process varies the timeframe of the selective etch steps as the cyclic etching process progresses. In an embodiment, the cyclic etching process that corresponds to the etching intensity over time plot of FIG. 3B may be called a dynamic cyclic etching process.

It should be noted that both of the etching intensity over time plots of FIGS. 3A-3B are illustrated for an embodiment where a cyclic etching process has a feature recipe intended to etch a layer stack substrate comprised of alternating silicon oxide layers and silicon nitride layers. Consequently, the Nitride Step corresponds to the first selective etch step of the etch cycle, and the Oxide Step corresponds to the second selective etch step of the etch cycle, in this embodiment.

FIG. 3A comprises a plot of the etching intensity over time for a version of the cyclic etching process with a constant first etch time and second etch time of the etch cycle. The etching intensity may be an optical emission spectroscopy signal as just one example technique to measure etch intensity. For example, in an embodiment where the etching tool comprises a plasma etcher, a gas analyzer may be used to monitor the composition of the outflow gas from a plasma etch chamber during the etching. As a result, the total time of the cyclic etching process depends on the number of etch cycles used to etch the features of the feature recipe. FIG. 3A further comprises example layer stack substrates that have been etched to the point in time of the etching intensity over time plot they are illustrated beneath. For example, a first etch time layer stack substrate 302 corresponds to the Start Nitride Step dotted line directly above it, and has not experienced any of the cyclic etching process yet.

The etching intensity plot over time of FIG. 3A starts with a minimal amount of intensity and then begins to ramp the intensity up at the Start Nitride Step, which begins the first etch cycle of the cyclic etching process. The etching intensity continues to linearly increase to a configurable maximum intensity, that once reached will begin to ramp down. While the intensity linearly decreases, the etching still continues, which may cause over etch (labeled Over Etch at the bottom of the plot). By using a selective etch process configured to etch a targeted layer, over etch damage to an under layer may be minimized. The small over etch timeframe may be used to ensure the completion of slower etch rate features (such as channel hole).

The first maximum reached may be the Nitride Step End Point, and that point corresponds to a second etch time as shown in second structure 304. At this time, the top silicon nitride layer of the second structure 304 has been etched. After reaching the Nitride Step End Point, the etching intensity linearly decreases back down to the initial value, which ends the first selective etch step. The cyclic etching process switches to the second etch step of the etch cycle to etch, in this embodiment, the silicon oxide layer of the layer stack at the point labeled Start Oxide Step.

The first Start Oxide Step corresponds to the second etch step of the etch cycle, and also corresponds to a third etch time as shown in third structure 306. The top silicon nitride layer of the third structure 306 has been etched with minimal over etch of the silicon oxide layer beneath. At the Start Oxide Step, the etching intensity begins to linearly ramp up and start the etching of the silicon oxide layer, which corresponds to starting the second selective etch step of the etch cycle. The etching intensity linearly increases to the same maximum level to the point labeled Oxide Step End Point, which corresponds to a fourth etching time as shown in the fourth structure 308. At this time, the upper silicon oxide layer of the fourth structure 308 has been etched.

The cyclic etching process then begins to ramp the etching intensity linearly down from the configurable maximum, and again over etch may occur. As a result of the selective etch process, over etch may be minimized on the underlying silicon nitride layer. Consequently, the oxide targeting selective etch step negligibly effects the underlying silicon nitride layer and may be used to ensure the completion of smaller etch rate features. The etching intensity linearly decreases to the initial level again, which may be the end of the second selective etch step, and completes an entire etch cycle.

At this point, the cyclic etching process switches to the first selective etch step, which begins a new etch cycle at the point labeled Start Nitride Step. The second Start Nitride Step corresponds to a fifth etch time as shown in the fifth structure 310. A single silicon nitride layer and a single silicon oxide layer have now been etched with minimal over etch to the underlying silicon nitride layer in the fifth structure 310. At this point, the new etch cycle proceeds through similar steps as described above, but corresponding to different etch times as shown in further structures 312, 314, 316, 318, as the cyclic etching process etches features into the layer stack. The cyclic etching process continues to linearly increase and linearly decrease the etching intensity based on which selective etch step may be currently etching until the number of etch cycles prescribed by the feature recipe have been completed.

It should be noted that the etch times for the first selective etch step and the second selective etch step of the cyclic etching process illustrated by the etching intensity over time plot of FIG. 3A, are the same in this embodiment. In other embodiments, the first selective etch step's first etch time may be different than the second selective etch step's second etch time, but may both remain constant themselves (the first etch time may be a constant, and the second etch time may be a constant, but they may not necessarily be the same constant).

FIG. 3B comprises a plot of the etching intensity over time for a version of the cyclic etching process with a dynamic first etch time and second etch time of the etch cycle. As a result, the cyclic etching process may be actively switched between the selective etch steps based on monitoring the composition of outflowing material in the etching tool. For example, in an embodiment where the etching tool comprises a plasma etcher, a gas analyzer may be used to monitor the composition of the outflow gas from a plasma etch chamber during the etching. In that same embodiment, if the gas analyzer detects a sharp drop in levels of the material being targeted by the active selective etch step, a controller may be used to switch to the next selective etch step. FIG. 3B further comprises example layer stack substrates that have been etched to the point in time of the etching intensity over time plot they are illustrated beneath. For example, a first etch time layer stack substrate 302 corresponds to the Start Nitride Step dotted line, and has not experienced any of the cyclic etching process yet.

The steps of the dynamic cyclic etching process that the plot of FIG. 3B illustrates are the same as the detailed description of FIG. 3A above. For the sake of brevity, they will not be repeated here. The difference between the plots of FIG. 3A and FIG. 3B may be that the etch times of the selective etch steps illustrated by the changing etching intensity plot in FIG. 3B increase as time progresses. It should be noted, however, that the first selective etch step's first etch time of the first etch cycle in FIG. 3B differs from the first selective etch step's first etch time of the second etch cycle illustrated in FIG. 3B. It should also be noted that the second selective etch step's second etch time of the first etch cycle in FIG. 3B differs from the second selective etch step's second etch time of the second etch cycle illustrated in FIG. 3B. In another embodiment, as the cyclic etching process illustrated in FIG. 3B continues, the first and second etch times may continue to increase.

In an embodiment, the etching intensity of the etching tool implementing the cyclic etching process of this disclosure may not be increased or decreased linearly. For example, in an embodiment, the etching intensity may be sinusoidally varied.

In an embodiment, the cyclic etching process (both the constant etch time and dynamic etch time versions) may be implemented by a plasma etching tool. In various other embodiments, any etching tool capable of implementing the cyclic etching process to etch high-aspect-ratio features may be used, such as deep reactive ion etching (DRIE), ion beam etching (IBE), electron cyclotron resonance (ECR) etching, or others. A plasma etching tool capable of etching different HAR features simultaneously by using the cyclic etching process of this disclosure will be discussed next.

FIG. 4 illustrates a plasma etching tool 400 that may implement the cyclic etching process of this disclosure in accordance with various embodiments.

FIG. 4 illustrates a plasma etching tool 400 for performing the cyclic etching process of this disclosure, for example illustrated in the flowchart in FIG. 1F. In various embodiments, the plasma etching tool 400 may be configured to selectively etch layer stack 104 using a first selective etch step and a second selective etch step. The first selective etch step comprises using a first gas chemistry that, when ignited into a plasma and used to etch layer stack 104, effectively etches the material that the first layer comprises with minimal damage to the second layer. The second selective etch step comprises using a second gas chemistry that, when ignited into a plasma and used to etch layer stack 104, effectively etches the material that the second layer comprises with minimal damage to the first layer. The plasma etching tool 400 may be configured to selectively etch layer stack 104 by switching between the first gas chemistry and the second gas chemistry.

In an embodiment where the first layer of the layer stack comprises silicon nitride and the second layer of the layer stack comprises silicon oxide, the first gas chemistry used may be one that selectively etches silicon nitride. For example, gases such as CHF₃, CH₂F₂, CH₃F, CF₄, SF₆, and NF₃ are mixed with Ar, Kr, O₂, CO₂, N₂, H₂, CH₄, or NO to ensure a high anisotropy and a high selectivity over silicon oxide (as well as silicon, which may be the material the substrate comprises). In one or more embodiments, silicon nitride layers may be etched using CH₃F/O₂ and CH₃F/CO₂. In other embodiments, silicon nitride layers may be etched using one or all of CH₃F, CH₂F₂, and CHF₃ combined with O₂. Other gases such as Ar, Kr, N₂, and etcetera may be used. In various embodiments, any plasma capable of etching silicon nitride selective to silicon oxide may be used.

In a similar embodiment where the first layer of the layer stack comprises silicon nitride and the second layer of the layer stack comprises silicon oxide, the second gas chemistry used may be one that selectively etches silicon oxide. For example, gases such as C₄F₆, C₄F₈, C₃F₈, CF₄, SF₆, NH₃, and NF₃ are mixed with O₂, or Ar to ensure a high anisotropy and a high selectivity over silicon nitride (as well as silicon, which may be the material the substrate comprises). In one or more embodiments, silicon oxide layers may be etched using C₃F₈, C₄F₆, C₄F₈, and O₂. In various embodiments, additional gases are used such as COS, CO, etc.

The plasma etching tool 400 comprises a plasma processing chamber 450 configured to sustain plasma directly above a substrate 402 loaded onto a substrate holder 410. A process gas, such as the first gas chemistry or the second gas chemistry mentioned above, may be introduced to the plasma processing chamber 450 through a gas inlet 422 and may be pumped out of the plasma processing chamber 450 through a gas outlet 424. The gas inlet 422 and the gas outlet 424 may comprise a set of multiple gas inlets and gas outlets, respectively. The gas flow rates, the gas chemistry used, and the chamber pressure may be controlled by an inlet gas flow control system 420 coupled to the gas inlet 422. The inlet gas flow control system 420 may also implement the cyclic etching process of this disclosure. The outflow gas composition may be monitored using an outlet gas flow control system 426 coupled to the gas outlet 424. The outflow gas composition results determined by the outlet gas flow control system 426 may be used as a dynamic trigger for switching between the selective etch steps of the etch cycle, such as the etch cycle illustrated in the plot of FIG. 3B, in an embodiment. In another embodiment, the plasma etching tool 400 may switch between the selective etch steps according to the etch times included in the feature recipe. The inlet gas flow control system 420 and the outlet gas flow control system 424 may comprise various components such as high-pressure gas canisters, valves (e.g., throttle valves), pressure sensors, gas flow sensors, gas analyzers, vacuum pumps, pipes, and electronically programmable controllers.

The plasma etching tool 400 may further comprise an RF bias power source 460 and an RF source power source 430. The RF bias power source 460 and the RF source power source 430 may be coupled to respective electrodes of the plasma etching tool 400. The substrate holder 410 may also be the electrode coupled to the RF bias power source 460. The RF source power source 430 is illustrated coupled to a helical electrode 432 coiled around a dielectric sidewall 416. In FIG. 4, the gas inlet 422 may be an opening in a top plate 412 and the gas outlet 424 may be an opening in a bottom plate 414. The top plate 412 and bottom plate 414 may be conductive and electrically connected to the system ground (a reference potential).

The plasma etching tool 400 illustrated in FIG. 4 is for example only. In various alternative embodiments, the plasma etching tool 400 may be configured with different couplings of the RF source power source 430 and the RF bias power source 460. In other embodiments, gas inlets and outlets may be coupled to sidewalls of the plasma processing chamber 450. In other embodiments, the outflow gas flow control system 426 does not actively monitor the gas composition of the gas flowing out of the plasma processing chamber 450 through the gas outlet 424. As a result, the plasma etching tool 400 instead may implement the cyclic etching process with a static etch cycle (like illustrated in the plot of FIG. 3A). In another embodiment, the plasma etching tool 400 may be capable of depositing and patterning a hard mask layer over the layer stack substrate, as well as etch the features of the feature recipe using the cyclic etching process of this disclosure.

Example embodiments of the invention are described below. Other embodiments can also be understood from the entirety of the specification as well as the claims filed herein.

Example 1. A method of forming a device, the method includes loading a substrate into an etch chamber, the substrate including an underlayer and a pair of a first layer and a second layer, the pair being stacked to form a layer stack. The method further includes forming a patterned hard mask layer over the layer stack, the patterned hard mask layer including a pattern for forming a first set of features and a pattern for forming a second set of features. And the method further includes using the patterned hard mask layer as an etch mask, performing a cyclic etching process to etch through the layer stack and expose the underlayer, each cycle of the cyclic etching process including a first etch step to selectively etch the first layer and a second etch step to selectively etch the second layer, the cyclic etching process being performed for a total number of cycles correlated to a total number of pairs in the layer stack, and where the cyclic etching process forms the first set of features and the second set of features, the first set of features having a different etch rate than the second set of features.

Example 2. The method of example 1, where the first set of features is a channel hole and the second set of features is a slit, the method further includes filling the first set of features with a channel stack and filling the second set of features with a gate stack.

Example 3. The method of one of examples 1 or 2, where a time to complete the first etch step increases between each cycle during the cyclic etching process.

Example 4. The method of one of examples 1 to 3, where a cycle time to complete the first etch step and the second etch step varies across each cycle during the cyclic etching process.

Example 5. The method of one of examples 1 to 4, further includes dynamically determining a cycle time to complete the first etch step and the second etch step using an end point detection process.

Example 6. The method of one of examples 1 to 5, where a cycle time to complete the first etch step and the second etch step remains constant across each cycle during the cyclic etching process.

Example 7. The method of one of examples 1 to 6, where a first etch time for the first etch step is based on etching through the associated first layer in forming the first set of features without etching an underlying second layer being exposed through the second set of features, and where a second etch time for the second etch step is based on etching through the associated second layer in forming the first set of features without etching an underlying first layer being exposed through the second set of features.

Example 8. The method of one of examples 1 to 7, where the first set of features have a first etch rate and the second set of features have a second etch rate, the first etch rate being at least about 10% greater than the second etch rate.

Example 9. The method of one of examples 1 to 8, where the first layer includes a silicon oxide layer, the second layer includes a silicon nitride layer, and the underlayer includes a semiconducting material, or a conductive material, or an etch stop layer.

Example 10. The method of one of examples 1 to 9, where the first layer is etched with a first etch chemistry including any of CHF₃, CH₂F₂, CH₃F, CF₄, SF₆, and NF₃ that are mixed with Ar, Kr, CO₂, O₂, N₂, H₂, CH₄, or NO and the second layer is etched with a second etch chemistry including any of C₄F₆, C₄F₈, C₃F₈, CF₄, SF₆, NH₃, and NF₃ that are mixed with COS, CO, O₂, or Ar.

Example 11. A method of forming a device, the method includes loading a substrate into an etch chamber, the substrate including an underlayer. The method further includes performing a first cyclic process to deposit a layer stack including alternating oxide and nitride layers, the first cyclic process including 2ⁿ cycles to form 2ⁿ alternating oxide and nitride layers, where n is an integer greater than 5. The method further includes forming a patterned hard mask layer over the layer stack, where the patterned hard mask layer includes a pattern for forming a first set of high aspect ratio features and a pattern for forming a second set of high aspect ratio features. And the method further includes using the patterned hard mask layer as an etch mask, performing a second cyclic process to etch through the 2ⁿ alternating oxide and nitride layers of the layer stack and expose the underlayer, each cycle of the second cyclic process including a first etch step to selectively etch the oxide layer and a second etch step to selectively etch the nitride layer, a total number of cycles in the second cyclic process being n, and where the second cyclic process forms the first set of high aspect ratio features and the second set of high aspect ratio features, the first set of high aspect ratio features having a different etch rate than the second set of high aspect ratio features.

Example 12. The method of example 11, where a time to complete the first etch step increases between each cycle during the second cyclic process.

Example 13. The method of one of examples 11 or 12, where a cycle time to complete the first etch step and the second etch step varies across each cycle during the second cyclic process.

Example 14. The method of one of examples 11 to 13, further includes dynamically determining a cycle time to complete the first etch step and the second etch step using an end point detection process.

Example 15. The method of one of examples 11 to 14, where a cycle time to complete the first etch step and the second etch step remains constant across each cycle during the second cyclic process.

Example 16. The method of one of examples 11 to 15, where the first set of high aspect ratio features is a channel hole and the second set of high aspect ratio features is a slit, the method further includes filling the first set of high aspect ratio features with a channel stack and filling the second set of high aspect ratio features with a gate stack.

Example 17. The method of one of examples 11 to 16, where a first etch time for the first etch step is based on etching through the associated oxide layer in forming the first set of high aspect ratio features without etching an underlying nitride layer being exposed through the second set of high aspect ratio features and a second etch time for the second etch step is based on etching through the associated nitride layer in forming the first set of high aspect ratio features without etching an underlying oxide layer being exposed through the second set of high aspect ratio features.

Example 18. The method of one of examples 11 to 17, where the first set of high aspect ratio features have a first etch rate and the second set of high aspect ratio features have a second etch rate, the first etch rate being at least about 10% greater than the second etch rate.

Example 19. The method of one of examples 11 to 18, where oxide layer includes silicon oxide, the nitride layer includes silicon nitride, and the underlayer includes a semiconducting material, or a conductive material, or an etch stop layer.

Example 20. A method of forming a 3D NAND device, the method includes having a substrate including an underlayer and a layer pair of a silicon oxide layer and a silicon nitride layer, the pair being stacked to form a layer stack. The method further includes determining a total number of layer pairs in the layer stack, where the total number of layer pairs is greater than 2″, where n is an integer greater than 5. The method further includes determining a number of etch cycles for a cyclic etching process based on the total number of layer pairs. The method further includes etching a plurality of gate patterns and channel holes through the layer stack using the cyclic etching process, the cyclic etching process being repeated for the number of etch cycles, each cycle including a first etching process to selectively etch the oxide layer and a second etching process to selectively etch the nitride layer. And the method further includes filling the plurality of gate patterns with a gate stack material and the channel holes with a channel material.

Example 21. A method for determining an etch cycle of a feature recipe includes receiving a layer stack substrate to be etched using a feature recipe, the feature recipe including a set of features and an etch depth. The method further includes positioning the layer stack substrate in an etching tool that includes a gas inlet and a gas outlet. The method further includes determining a feature of the set of features with the slowest etch rate. The method further includes etching the feature with the slowest etch rate into the layer stack substrate using an oxide selective etch process. The method further includes monitoring an oxide selective gas composition passing through the gas outlet for a decrease in concentration of oxides. The method further includes, in response to detecting the decrease in concentration of oxides, determining an oxide selective timeframe. The method further includes, in response to recording the oxide selective timeframe, etching the feature with the slowest etch rate into the layer stack substrate using a nitride selective etch process. The method further includes monitoring a nitride selective gas composition passing through the gas outlet for a decrease in concentration of nitrides. The method further includes, in response to detecting the decrease in concentration of nitrides, determining a nitride selective timeframe. And the method further includes, in response to determining the nitride selective timeframe, determining an etch cycle.

Example 22. The method of example 21, where the etch cycle includes etching using the oxide selective etch process for the oxide selective timeframe. And the etch cycle further includes etching using the nitride selective etch process for the nitride selective timeframe.

Example 23. The method of one of examples 21 or 22, where the oxide selective timeframe includes the amount of time from the start of the oxide selective etch process to the detection of the sharp decrease in concentration of oxides.

Example 24. The method of one of examples 21 to 23, where the nitride selective timeframe includes the amount of time from the start of the nitride selective etch process to the detection of the sharp decrease in concentration of nitrides.

Example 25. The method of one of examples 21 to 24, where the oxide selective etch process includes etching using an oxide selective gas chemistry that etches materials included of oxides.

Example 26. The method of one of examples 21 to 25, where the nitride selective etch process includes etching using a nitride selective gas chemistry that etches materials included of nitrides.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of forming a device, the method comprising:
loading a substrate into an etch chamber, the substrate comprising an underlayer and a pair of a first layer and a second layer, the pair being stacked to form a layer stack;
forming a patterned hard mask layer over the layer stack, the patterned hard mask layer comprising a pattern for forming a first set of features and a pattern for forming a second set of features; and
using the patterned hard mask layer as an etch mask, performing a cyclic etching process to etch through the layer stack and expose the underlayer, each cycle of the cyclic etching process comprising a first etch step to selectively etch the first layer and a second etch step to selectively etch the second layer, the cyclic etching process being performed for a total number of cycles correlated to a total number of pairs in the layer stack, and wherein the cyclic etching process forms the first set of features and the second set of features, the first set of features having a different etch rate than the second set of features.

2. The method of claim 1, wherein the first set of features is a channel hole and the second set of features is a slit, the method further comprising:
filling the first set of features with a channel stack and filling the second set of features with a gate stack.

3. The method of claim 1, wherein a time to complete the first etch step increases between each cycle during the cyclic etching process.

4. The method of claim 1, wherein a cycle time to complete the first etch step and the second etch step varies across each cycle during the cyclic etching process.

5. The method of claim 4, further comprising dynamically determining a cycle time to complete the first etch step and the second etch step using an end point detection process.

6. The method of claim 1, wherein a cycle time to complete the first etch step and the second etch step remains constant across each cycle during the cyclic etching process.

7. The method of claim 1,
wherein a first etch time for the first etch step is based on etching through the associated first layer in forming the first set of features without etching an underlying second layer being exposed through the second set of features, and
wherein a second etch time for the second etch step is based on etching through the associated second layer in forming the first set of features without etching an underlying first layer being exposed through the second set of features.

8. The method of claim 1, wherein the first set of features have a first etch rate and the second set of features have a second etch rate, the first etch rate being at least about 10% greater than the second etch rate.

9. The method of claim 1, wherein the first layer comprises a silicon oxide layer, the second layer comprises a silicon nitride layer, and the underlayer comprises a semiconducting material, or a conductive material, or an etch stop layer.

10. The method of claim 1, wherein the first layer is etched with a first etch chemistry comprising any of CHF₃, CH₂F₂, CH₃F, CF₄, SF₆, and NF₃ that are mixed with Ar, Kr, CO₂, O₂, N₂, H₂, CH₄, or NO and the second layer is etched with a second etch chemistry comprising any of C₄F₆, C₄F₈, C₃F₈, CF₄, SF₆, NH₃, and NF₃ that are mixed with COS, CO, O₂, or Ar.

11. A method of forming a device, the method comprising:
loading a substrate into an etch chamber, the substrate comprising an underlayer;
performing a first cyclic process to deposit a layer stack comprising alternating oxide and nitride layers, the first cyclic process comprising 2ⁿ cycles to form 2ⁿ alternating oxide and nitride layers, where n is an integer greater than 5;
forming a patterned hard mask layer over the layer stack, wherein the patterned hard mask layer comprises a pattern for forming a first set of high aspect ratio features and a pattern for forming a second set of high aspect ratio features; and
using the patterned hard mask layer as an etch mask, performing a second cyclic process to etch through the 2ⁿ alternating oxide and nitride layers of the layer stack and expose the underlayer, each cycle of the second cyclic process comprising a first etch step to selectively etch the oxide layer and a second etch step to selectively etch the nitride layer, a total number of cycles in the second cyclic process being n, and wherein the second cyclic process forms the first set of high aspect ratio features and the second set of high aspect ratio features, the first set of high aspect ratio features having a different etch rate than the second set of high aspect ratio features.

12. The method of claim 11, wherein a time to complete the first etch step increases between each cycle during the second cyclic process.

13. The method of claim 11, wherein a cycle time to complete the first etch step and the second etch step varies across each cycle during the second cyclic process.

14. The method of claim 13, further comprising dynamically determining a cycle time to complete the first etch step and the second etch step using an end point detection process.

15. The method of claim 11, wherein a cycle time to complete the first etch step and the second etch step remains constant across each cycle during the second cyclic process.

16. The method of claim 11, wherein the first set of high aspect ratio features is a channel hole and the second set of high aspect ratio features is a slit, the method further comprising:
filling the first set of high aspect ratio features with a channel stack and filling the second set of high aspect ratio features with a gate stack.

17. The method of claim 11, wherein a first etch time for the first etch step is based on etching through the associated oxide layer in forming the first set of high aspect ratio features without etching an underlying nitride layer being exposed through the second set of high aspect ratio features and a second etch time for the second etch step is based on etching through the associated nitride layer in forming the first set of high aspect ratio features without etching an underlying oxide layer being exposed through the second set of high aspect ratio features.

18. The method of claim 11, wherein the first set of high aspect ratio features have a first etch rate and the second set of high aspect ratio features have a second etch rate, the first etch rate being at least about 10% greater than the second etch rate.

19. The method of claim 11, wherein oxide layer comprises silicon oxide, the nitride layer comprises silicon nitride, and the underlayer comprises a semiconducting material, or a conductive material, or an etch stop layer.

20. A method of forming a 3D NAND device, the method comprising:
having a substrate comprising an underlayer and a layer pair of a silicon oxide layer and a silicon nitride layer, the pair being stacked to form a layer stack;
determining a total number of layer pairs in the layer stack, wherein the total number of layer pairs is greater than 2ⁿ, wherein n is an integer greater than 5;
determining a number of etch cycles for a cyclic etching process based on the total number of layer pairs;
etching a plurality of gate patterns and channel holes through the layer stack using the cyclic etching process, the cyclic etching process being repeated for the number of etch cycles, each cycle comprising a first etching process to selectively etch the oxide layer and a second etching process to selectively etch the nitride layer; and
filling the plurality of gate patterns with a gate stack material and the channel holes with a channel material.
